(19) United States
(12) Patent Application Publication
(10) Pub. No.: US 2026/0271728 A1
(43) Pub. Date: Sep. 10, 2026

(54) SEMICONDUCTOR DEVICE AND MANUFACTURING METHOD

(71) Applicants: Kabushiki Kaisha Toshiba, Kawasaki-shi (JP); Toshiba Electronic Devices & Storage Corporation, Kawasaki-shi (JP)

(72) Inventors: Keisuke KOZAKI, Nomi Ishikawa (JP); Kenta OSHINO, Kanazawa Ishikawa (JP); Hiroki TSUDA, Kanazawa Ishikawa (JP); Hirofumi OKEDA, Kanazawa Ishikawa (JP)

(21) Appl. No.: 19/309,571

(22) Filed: Aug. 25, 2025

(30) Foreign Application Priority Data
Mar. 5, 2025 (JP) 2025-034713

(51) Int. Cl. H01L 23/00; H10D 62/10

(52) U.S. Cl. CPC H10W 42/00; H10D 62/104

(57) ABSTRACT

According to one embodiment, a semiconductor device has a semiconductor substrate with an element region and a terminal region surrounding the element region. A first electrode is on one side of the semiconductor substrate, and a second electrode is on the other side of the semiconductor substrate in the element region. An insulating film is on the substrate. A control wiring is on the insulating film. A terminal electrode is on the insulating film in the terminal region. A protective film is on the insulating film. The insulating film has an upper surface contacting the protective film in the terminal region. The upper surface has a first upper surface portion and a second upper surface portion. A distance between the first electrode and the second upper surface portion is less than a distance between the first electrode and the first upper surface portion.

### CROSS-REFERENCE TO RELATED APPLICATION

This application is based upon and claims the benefit of priority from Japanese Patent Application No. 2025-034713, filed Mar. 5, 2025, the entire contents of which are incorporated herein by reference.

### FIELD

Embodiments described herein relate generally to a semiconductor device and a manufacturing method thereof.

### BACKGROUND

In a semiconductor device, such as a metal-oxide-semiconductor field effect transistor (MOSFET), there is a structure that increases a migration path distance along the upper surface of a semiconductor substrate by forming a groove between a source electrode and a gate wiring on the upper surface of the semiconductor substrate to limit movement (migration) of moisture.

### BRIEF DESCRIPTION OF THE DRAWINGS

FIG. 1 is a schematic plan view illustrating a semiconductor device according to a first embodiment.

FIG. 2A is a cross-sectional view of a semiconductor device according to a first embodiment.

FIG. 2B is a cross-sectional view of a semiconductor device according to a first embodiment.

FIG. 3A is an enlarged cross-sectional view of a semiconductor device according to a first modification of a first embodiment.

FIG. 3B is an enlarged cross-sectional view of a semiconductor device according to a first modification of a first embodiment.

FIG. 4 is a cross-sectional view of a semiconductor device according to a second embodiment.

FIG. 5 is a cross-sectional view of a semiconductor device according to a third embodiment.

FIG. 6 is a cross-sectional view of a semiconductor device according to a fourth embodiment.

FIG. 7 is a cross-sectional view of a semiconductor device according to a fifth embodiment.

FIG. 8A is a plan view of a semiconductor device according to a sixth embodiment.

FIG. 8B is a plan view of the semiconductor device according to a sixth embodiment.

FIG. 9 is a plan view of a semiconductor device according to a seventh embodiment.

FIG. 10 is a plan view of a semiconductor device according to an eighth embodiment.

FIG. 11 is a cross-sectional view of a semiconductor device according to a ninth embodiment.

FIG. 12 is an enlarged cross-sectional view of a semiconductor device according to a ninth embodiment.

FIG. 13 is a cross-sectional view of a semiconductor device according to a tenth embodiment.

FIG. 14 is a cross-sectional view of a semiconductor device according to a comparative example.

FIG. 15 is another cross-sectional view of the semiconductor device according to the comparative example.

### DETAILED DESCRIPTION

Embodiments provide a semiconductor device having improved moisture resistance.

In general, according to one embodiment, a semiconductor device includes a semiconductor substrate having an element region and a terminal region surrounding the element region. A first electrode is on a first side of the semiconductor substrate. A second electrode is on a second side of the semiconductor substrate in the element region. An insulating film is on the semiconductor substrate. A control wiring is on the insulating film. A terminal electrode has a portion on the semiconductor substrate with the insulating film interposed therebetween in the terminal region. A protective film is on the insulating film. The insulating film has an upper surface contacting the protective film in the terminal region. The upper surface has a first upper surface portion and a second upper surface portion. And a distance between the first electrode and the second upper surface portion is less than a distance between the first electrode and the first upper surface portion.

According to another embodiment, a semiconductor device includes a semiconductor substrate having an element region and a terminal region surrounding the element region, a first electrode on a first side of the semiconductor substrate, a second electrode on a second side of the semiconductor substrate in the element region, an insulating film on the second side of the semiconductor substrate in the terminal region, the insulating film having a first portion with a first thickness and a second portion with a second thickness less than the first thickness, a control wiring on the insulating film in the terminal region, a terminal electrode with a portion on the semiconductor substrate with the insulating film interposed therebetween in the terminal region, and a protective film on the insulating film, the protective film directly contacting a first upper surface of the first portion of the insulating film.

According to one embodiment, a manufacturing method of a semiconductor device includes: preparing a semiconductor substrate having an element region having an upper surface electrode and a terminal region surrounding the element region; forming an insulating film on the semiconductor substrate; forming a terminal electrode on the insulating film in the terminal region; a recess portion in the insulating film by partially removing a portion of the insulating film; and forming a protective film on the recess portion of the insulating film.

Hereinafter, certain example embodiments of the present disclosure will be described with reference to the accompanying drawings.

It is noted that the drawings are schematic or conceptual illustrations, and, as such, the depicted relationships between the dimensions, such thicknesses and the widths, of each portion, the relative size ratios between the portions, and the like are not necessarily the same as actual ones. Further, even when the same portions are being represented, the dimensions and the like of portions may be different depending on the drawing.

For example, in a cross-sectional view illustrated in the present specification, a stacked structure is illustrated, but the depicted thickness ratios of the various layers of the stacked structure is not necessarily the same as the actual one. That is, even if one layer is shown to be thicker than another layer in the cross-sectional view, in reality, the thickness of one layer and the thickness of the other layer may be substantially the same, or the one layer may be thinner than the other layer. That is, the dimensions illustrated in the drawings of the present specification may be different from the actual one.

A direction from a first electrode 11 to a second electrode 12 is defined as a Z direction. One direction intersecting the Z direction is defined as an X direction, and a direction intersecting the X and Z directions is defined as a Y direction. In the present embodiment, although the X direction, the Y direction, and the Z direction are shown to be orthogonal to each other, the respective directions may intersect each other without being limited to an orthogonal relationship therebetween.

For the sake of description, a positive direction in the Z direction is referred to as “upward” and a negative direction in the Z direction is referred to as “downward”. However, the directions of “upward” and “downward” are not limited to the direction of gravity or the direction when a semiconductor device is mounted. When a vertical positional relationship (e.g., a height difference) between regions at different positions on the XY plane is being described, the positions (levels) of the regions in the Z direction are compared with each other.

In the following descriptions, notations n⁺, n, n⁻, p⁺, p, and p⁻ each represent a relatively high and low state of impurity (dopant) concentration for each conductivity type. That is, n⁺ indicates that n-type impurity concentration is relatively higher than n, and n⁻ indicates that n-type impurity concentration is relatively lower than n. Further, p⁺ indicates that p-type impurity concentration is relatively higher than p, and p⁻ indicates that p-type impurity concentration is relatively lower than p. It is noted that, in some cases, n⁺ type and n⁻ type may be simply referred to as n-type, and p⁺ type and p⁻ type may be simply referred to as p-type.

It is noted that, in the present specification and each drawing, elements substantially similar to those previously described with reference to an earlier drawings will generally be denoted by the same reference symbols, and detailed descriptions thereof will be omitted as appropriate.

### First Embodiment

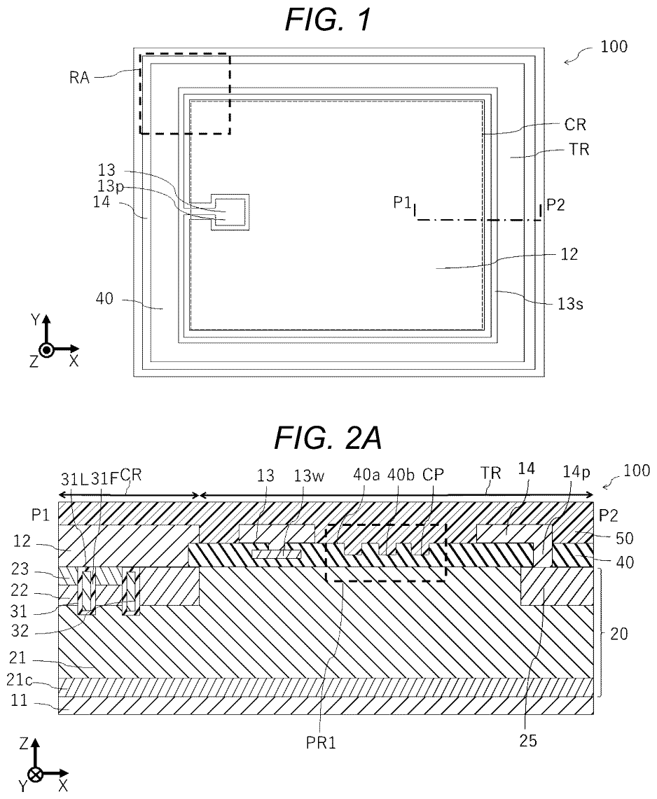

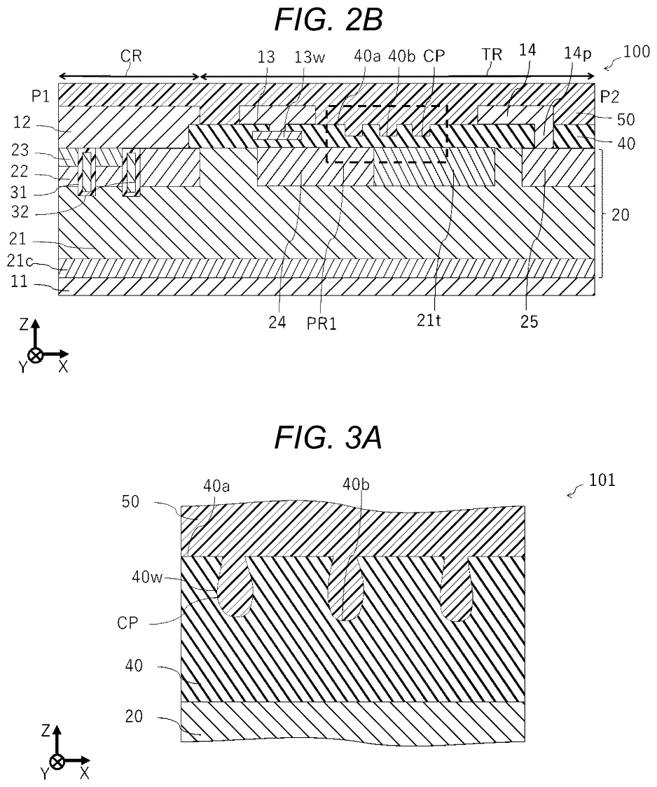

FIG. 1 is a schematic plan view of a semiconductor device 100 according to a first embodiment. FIGS. 2A and 2B are cross-sectional views each taken along line P1-P2 illustrated in FIG. 1. FIGS. 3A and 3B are enlarged cross-sectional views of a region PR1 illustrated in FIGS. 2A and 2B.

The semiconductor device 100 illustrated in FIG. 1 is, for example, a MOSFET. The semiconductor device 100 has an element region CR (a region surrounded by dashed lines in FIG. 1) in which an element such as a MOSFET is formed, and a terminal region TR surrounding this element region. The outer edge of the element region CR is located at the outer edge of a second semiconductor region 22 (a base region) of the semiconductor device 100.

In the element region CR of a semiconductor substrate 20 (refer to FIG. 2A), a MOSFET or the like is formed. The second electrode 12 (upper surface electrode) and a control wiring 13 are provided on the semiconductor substrate 20. It is noted that at least a part of the control wiring 13 may be located in the terminal region TR. The second electrode 12 is, for example, a source electrode. When the semiconductor device is turned on, the current flows mainly to the element region CR through the second electrode 12. The control wiring 13 includes a pad portion 13p, an outer peripheral portion 13s surrounding the second electrode 12, and a wiring 13w connected to the outer peripheral portion 13s and provided in an insulating film 40 as illustrated in FIG. 2A. The potential between the outer peripheral portion 13s and the wiring 13w is controlled by applying a voltage to the pad portion 13p. The insulating film 40 is provided on the semiconductor substrate 20. As shown in FIG. 2A, the first electrode 11 (a drain electrode) is provided on the lower surface of the semiconductor substrate 20.

In the terminal region TR, a terminal electrode 14 is provided on the insulating film 40 to surround the element region CR. The terminal electrode 14 is provided, for example, in the shape of a continuous ring (annular or frame-like structure). The upper surface of the insulating film 40 has a first upper surface 40a and a second upper surface 40b (see FIG. 2A) between the element region CR and the terminal electrode 14. The second upper surface 40b is the bottom surface of a recess portion CP, (see FIG. 2A). The second upper surface 40b can surround the element region CR. The protective film 50 is not specifically illustrated in FIG. 1, but see FIG. 2A.

It is noted that, although FIG. 1 can be used to explain the first embodiment, the P1-P2 line illustrated in FIG. 1 also corresponds to cross sections that will be explained for subsequent embodiments with other drawings.

FIGS. 2A and 2B are XZ cross-sectional views taken along the P1-P2 line illustrated in FIG. 1. The P1-P2 cross-sectional views illustrated in FIGS. 2A and 2B show an example in which the semiconductor device 100 has a MOSFET in the element region CR. A description will be given with reference to FIG. 2A.

The semiconductor device 100 has the first electrode 11, a first semiconductor region 21 (a n⁻ type drift region) of a first conductivity type, which is provided on the first electrode 11, the second semiconductor region 22 (a p-type base region) of a second conductivity type, which is provided on the first semiconductor region 21, and a third semiconductor region 23 (a n⁺ type source region) of the first conductivity type, which is provided on the second semiconductor region 22.

The first semiconductor region 21 also has a second conductivity type contact region 21c (a n⁺ type drain region) in contact with the first electrode 11.

The semiconductor device 100 may also have a fourth semiconductor region 24 provided on the first semiconductor region 21, as illustrated in FIG. 2B. The fourth semiconductor region 24 is located closer to the terminal electrode 14 than to the second semiconductor region 22. Although one fourth semiconductor region 24 is illustrated in FIG. 2B, a plurality of fourth semiconductor regions 24 may be provided in a direction from the element region CR to the terminal region TR. The fourth semiconductor region 24 is, for example, a p-type reduced surface field (RESURF) region. The fourth semiconductor region 24 includes a portion located between the second electrode 12 and the terminal electrode 14 in the X direction. The fourth semiconductor region 24 also includes a portion located between the control wiring 13 and the terminal electrode 14 in the X direction.

Furthermore, the semiconductor device 100 may have a surface region 21t of the first conductivity type, which is located in the positive Z direction (toward the surface) in the first semiconductor region 21, as illustrated in FIG. 2B. The surface region 21t of the first semiconductor region 21 is located farther away from the element region CR than the fourth semiconductor region 24 on the upper surface of the semiconductor substrate 20. The surface region 21t has a higher impurity concentration of the first conductivity type than that of the first semiconductor region 21 located below the surface region 21t. Desirably, the surface region 21t has a higher impurity concentration of the first conductivity type than that of the first semiconductor region 21 located below the second semiconductor region 22 of the element region CR. The surface region 21t is, for example, a n-type RESURF region. The fourth semiconductor region 24 and the surface region 21t may surround the element region CR in an XY plane. The surface region 21t includes a portion located between the second electrode 12 and the terminal electrode 14 in the X direction. The surface region 21t includes a portion located between the control wiring 13 and the terminal electrode 14 in the X direction.

Referring back to FIG. 2A, in the element region CR, a gate insulating portion 31 is provided in the semiconductor substrate 20 from the second electrode 12 toward the first semiconductor region 21. A gate electrode 32 is provided in the gate insulating portion 31. The gate electrode 32 faces the second semiconductor region 22 with the gate insulating portion 31 interposed therebetween. The gate insulating portion 31 and the gate electrode 32 are disposed in the X direction and extend in the Y direction. The gate insulating portion 31 includes a gate insulating film 31F formed to be thin between the semiconductor substrate 20 and the gate electrode 32, and a gate insulation layer 31L formed to be thick between the second electrode 12 and the gate electrode 32.

The insulating film 40 is provided on the semiconductor substrate 20. The wiring 13w is electrically connected to the control wiring 13 and is provided in the insulating film 40.

The gate electrode 32 can be electrically connected to the wiring 13w at a position not depicted in FIG. 2A. The wiring 13w is electrically connected to at least a part of the gate electrode 32 extending in the Y direction in FIG. 1. For example, the gate electrode 32 and the wiring 13w contact each other at a Y-direction end of the gate electrode 32.

The terminal electrode 14 is at least in part provided on the insulating film 40 in the terminal region TR. The terminal electrode 14 is electrically connected to the semiconductor substrate 20. The terminal electrode 14 has a connection electrode 14p extending through the insulating film 40 and connected to the semiconductor substrate 20. The semiconductor substrate 20 has a terminal semiconductor region 25 electrically connected to the connection electrode 14p. The terminal semiconductor region 25 contains impurities of the first conductivity type, and the impurity concentration of the first conductivity type is higher than that of the first semiconductor region 21.

The connection electrode 14p can surround the element region CR in the XY plane. A portion of the terminal electrode 14 extends on an upper surface of the insulating film 40 in a direction toward the element region CR from the connection electrode 14p.

The upper surface of the insulating film 40 has the first upper surface 40a and the second upper surface 40b at one or more positions between the element region CR and the terminal electrode 14. That is, the upper surface of the insulating film 40 is provided with unevenness between the element region CR and the terminal electrode 14. A distance in the Z direction between the second upper surface 40b and the first electrode 11 is less than a distance between the first upper surface 40a and the first electrode 11. The second upper surface 40b is, for example, the bottom surface of a recess portion CP and is provided at a position where a distance in the Z direction between the second upper surface 40b and the semiconductor substrate 20 is shorter than a distance in the Z direction between the first upper surface 40a and the semiconductor substrate 20. Although three second upper surfaces 40b portions are illustrated in FIG. 2A, the present embodiment also includes examples with any number of second upper surfaces 40b that might be provided spaced from each other in the X direction in FIG. 2A.

A thickness of the insulating film 40 in the Z direction below the second upper surface 40b is less than a thickness of the insulating film 40 in the Z direction below the first upper surface 40a. However, the step distance in the Z direction between the first upper surface 40a and the second upper surface 40b is less than the total thickness of the insulating film 40 in the Z direction in the first upper surface 40a. That is, the second upper surface 40b is farther away from the first electrode 11 in the Z direction than is the upper surface of the semiconductor substrate 20. In other words, a distance in the Z direction between the second upper surface 40b and the first electrode 11 is larger than a distance in the Z direction between the upper surface of the semiconductor substrate 20 and the first electrode 11.

The first upper surface 40a is overall a flat surface at a single level (height).

The protective film 50 is provided on the insulating film 40. The protective film 50 contacts the second electrode 12, the control wiring 13, and the terminal electrode 14. The protective film 50 can be in direct contact with the first upper surface 40a of the insulating film 40.

Next, an example of each material will be described.

Each of the first electrode 11 and the second electrode 12 is, for example, a metal such as aluminum (Al) or copper (Cu).

Each of the pad portion 13p and the outer peripheral portion 13s of the control wiring 13 is, for example, a metal such as Al or Cu. The wiring 13w is, for example, conductive polysilicon (doped polysilicon).

The terminal electrode 14 is, for example, a metal such as Al or Cu.

The semiconductor substrate 20 has the first semiconductor region 21, the second semiconductor region 22, the third semiconductor region 23, the fourth semiconductor region 24 as depicted in FIG. 2B, and the terminal semiconductor region 25 comprises, for example, silicon (Si). The n-type conductivity type semiconductor region is formed, for example, by injecting (implanting) n-type dopants (e.g., phosphorous) and performing an annealing process. The p-type conductivity type semiconductor region is formed, for example, by injecting (implanting) p-type dopants (e.g., boron) and performing an annealing process.

The gate insulating portion 31 is, for example, an oxide film such as silicon oxide. The gate electrode 32 is, for example, conductive polysilicon.

The insulating film 40 is, for example, a silicon oxide (e.g., SiO₂).

The protective film 50 is, for example, a polyimide. In some examples, protective film 50 may be, an epoxy resin.

Next, the operation of the semiconductor device 100 will be described.

First, the operation of the element region CR will be described with reference to FIG. 2A. When a voltage equal to or greater than a threshold voltage is applied to the gate electrode 32 while a positive voltage (with respect to the second electrode 12) is applied to the first electrode 11, an inversion layer (channel) of the first conductivity type is generated in the second semiconductor region 22. Electrons are injected into the first semiconductor region 21 from the second electrode 12 through the third semiconductor region 23 and the inversion layer of the second semiconductor region 22, and the MOSFET is turned on.

Next, when the voltage applied to the gate electrode 32 becomes less than the threshold voltage, the inversion layer of the first conductivity type formed in the second semiconductor region 22 disappears, the injection of electrons stops, and the MOSFET is turned off.

Next, the off-state of the MOSFET formed in the element region CR will be described. When the voltage applied to the gate electrode 32 is less than the threshold voltage, a positive (with respect to the second electrode 12) voltage applied to the first electrode 11 promotes depletion of the semiconductor substrate 20 and maintains the breakdown voltage. A depletion layer extends from an interface between the first semiconductor region 21 and the second semiconductor region 22 into the first semiconductor region 21, and the depletion layer extends to the terminal region TR near the upper surface of the semiconductor substrate 20, thereby preventing concentration of an electric field and maintaining the breakdown voltage.

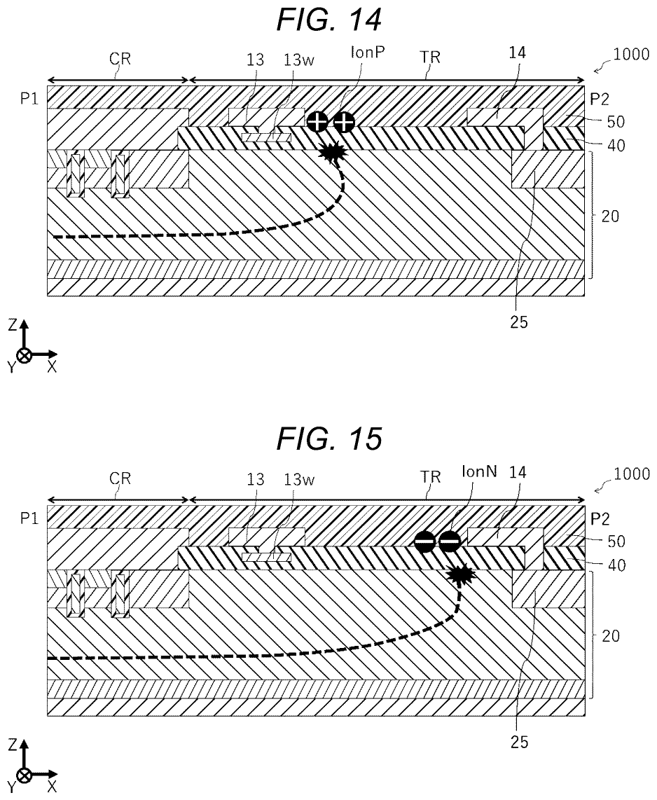

Next, a configuration of a comparative example will be described. FIGS. 14 and 15 illustrate cross-sectional views of a semiconductor device 1000 according to the comparative example. In FIGS. 14 and 15, the upper surface of the insulating film 40 is formed to be flat in the region between the control wiring 13 and the terminal electrode 14. In FIGS. 14 and 15, a dotted line represent extension of a depletion layer. Moisture and ions may move along the interface between the insulating film 40 and the protective film 50. For example, when the voltage of the control wiring 13 is lower than the voltage of the terminal electrode 14, then as shown in FIG. 14, a positive ion IonP will move toward the control wiring 13.

In this manner, when positive ions are locally present on the upper surface of the insulating film 40 in the vicinity of the control wiring 13, the extension of the depletion layer is prevented in a portion of the upper surface of the semiconductor substrate 20, which faces the positive ions with the insulating film 40 interposed therebetween. That is, in the portion of the upper surface of the semiconductor substrate 20 which faces the accumulated positive ions, a significant spatial change in the voltage may occur, and thus there is a risk of electric field concentration. In the portion of the upper surface of the semiconductor substrate 20, which faces the positive ions, there is a risk of chip destruction or damage.

FIG. 15 illustrates a case in which negative ions are locally present in the vicinity of the terminal electrode 14 on the upper surface of the insulating film 40. In a portion of the upper surface of the semiconductor substrate 20 which faces the negative ions with the insulating film 40 interposed therebetween, extension of a depletion layer is promoted. However, the terminal electrode 14 is connected to the first electrode 11 at the edge of the chip or the like, and the terminal electrode 14 thus has, for example, a voltage equal to a drain voltage. In the portion of the upper surface of the semiconductor substrate 20, which faces the terminal electrode 14 with the insulating film 40 interposed therebetween, charges are induced by the voltage of the terminal electrode 14. In the portion of the upper surface of the semiconductor substrate 20 which faces the terminal electrode 14 with the insulating film 40 interposed therebetween, the extension of the depletion layer is prevented by these induced charges. Therefore, since negative ions are locally present in the vicinity of the terminal electrode 14 on the upper surface of the insulating film 40, the depletion layer may stop below the terminal electrode 14, and an electric field may be concentrated at the portion of the upper surface of the semiconductor substrate 20 which faces the negative ions. Breakdown may occur in this portion of the upper surface of the semiconductor substrate 20.

In addition, due to differences in thermal expansion coefficients of the respective materials at high temperatures and also swelling due to humidity, layer peeling (delamination) may occur between the insulating film 40 and the protective film 50 in the terminal region TR. In such a case, moisture due to high humidity will generally be accumulated at the peeling interface, and movable ions within the moisture affect the electric field at the surface of the semiconductor substrate 20, leading to deterioration in the breakdown voltage and an increase in leakage.

With the semiconductor device 100, adhesion between the insulating film 40 and the protective film 50 can be improved, and thus reliability of the semiconductor device can be improved. Since unevenness is formed at an interface between the insulating film 40 and the protective film 50, a migration path distance along the interface between the insulating film 40 and the protective film 50 can be increased. Since the unevenness is formed at the interface between the insulating film 40 and the protective film 50, adhesion between the insulating film 40 and the protective film 50 can be improved. Adhesion between the insulating film 40 and the protective film 50 can be improved, movement of moisture (and ions contained in moisture) can be limited between the insulating film 40 and the protective film 50, and deterioration in the breakdown voltage of the semiconductor device can be avoided. Even if humidity of the environment is high and moisture and ions (contained in moisture) are present between the insulating film 40 and the protective film 50, deterioration in the breakdown voltage can be prevented, and moisture resistance can be improved.

The semiconductor device 100 improves the adhesion between the insulating film 40 and the protective film 50 will also preventing the movement of moisture and ions contained in moisture between the insulating film 40 and the protective film 50, thereby making it possible to prevent deterioration in the breakdown voltage and avoid an increase in current leakage under high temperature, high humidity, and high voltage.

The semiconductor device 100 limits the movement of moisture (and ions contained in moisture) by increasing a migration path distance from the terminal electrode 14 to the second electrode 12 or the control wiring 13 along the interface between the insulating film 40 and the protective film 50. In addition, since the longer migration path distance functions to improve the adhesion between the insulating film 40 and the protective film 50 this prevents or reduces peeling therebetween, and it is thus possible to further avoid the movement of moisture and ions contained in moisture that might be associated with peeling.

Furthermore, by selecting a material that has a property of absorbing water and swelling as a material for the protective film 50, adhesion can be further improved. A material that has the property of absorbing water and swelling is, for example, polyimide. Since the protective film 50 swells, the recess portion CP in the upper surface of the insulating film 40 can be reliably filled.

In the semiconductor device 100, the migration path distance along the interface between the insulating film 40 and the protective film 50 is increased, thereby preventing the movement of moisture and ions contained in moisture. Since the movement of ions caused by a voltage difference between the control wiring 13 and the terminal electrode 14 is prevented, the concentration of the electric field in the semiconductor substrate 20 can be prevented, and deterioration in the breakdown voltage can be prevented.

According to the semiconductor device 100, the step in the Z direction between the first upper surface 40a and the second upper surface 40b is formed to be less than the thickness of the insulating film 40 in the Z direction on the first upper surface 40a. The distance in the Z direction between the second upper surface 40b and the first electrode 11 is greater than the distance in the Z direction between the upper surface of the semiconductor substrate 20 and the first electrode 11. Compared to a semiconductor device 110 illustrated in FIG. 13, in the present embodiment, the upper surface of the semiconductor substrate 20 can be formed to have a flatter shape.

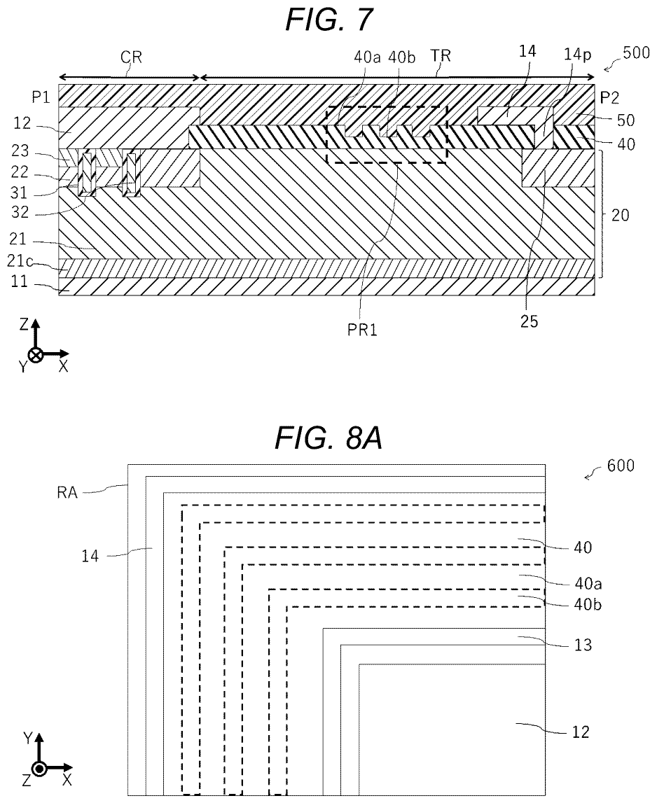

When the second electrode 12 is at a lower voltage than that of the first electrode 11, moisture or ions may move toward the second electrode 12 (or the terminal electrode 14) at the interface between the insulating film 40 and the protective film 50. Here, by providing the first upper surface 40a and the second upper surface 40b on the upper surface of the insulating film 40, the migration path distance from the terminal electrode 14 to the second electrode 12 or the control wiring 13 becomes longer along the interface between the insulating film 40 and the protective film 50. Therefore, the movement of moisture and ions contained in moisture can be prevented. In other words, according to the semiconductor device 100, the movement of moisture and ions contained in moisture can be limited between the terminal electrode 14 and an electrode to which a lower voltage than that of the terminal electrode 14 is applied (the second electrode 12 in FIG. 7 and the control wiring 13 in FIG. 2A).

In the example shown in FIG. 2A, the recess portion CP is formed by, for example, chemical dry etching (CDE) or reactive ion etching (RIE). As illustrated in FIG. 2A, the recess portion CP has a side surface extending in the Z direction.

Next, the uneven shape of the upper surface of the insulating film 40 will be described with reference to FIGS. 3A and 3B as a modification of the first embodiment. According to such a modification (and those discussed below), adhesion between the insulating film 40 and the protective film 50 can be further improved by an anchor effect associated with the protective film 50 that fills the recess portion CP. The structure of the recess portion CP can prevent peeling (separation) between the insulating film 40 and the protective film 50 in the Z direction.

In the vicinity of the bottom surface of the recess portion CP, a width of the protective film 50 filling the recess portion CP is formed to be wider in the X direction than a width of a portion located in the positive Z direction, and this exerts an anchor effect to restrict the peel off of the protective film 50 in the positive direction in the Z direction. When the protective film 50 is made of a swelling material, an even higher anchor effect can be expected.

Furthermore, as illustrated in FIG. 2B, the semiconductor device 100 can further prevent deterioration in the breakdown voltage when the fourth semiconductor region 24 and the surface region 21t are provided. The fourth semiconductor region 24 and the surface region 21t can reduce the concentration of the electric field in the terminal region TR of the semiconductor substrate 20. The fourth semiconductor region 24 and the surface region 21t can reduce the concentration of the electric field in the terminal region TR even when charges such as ions are present between the insulating film 40 and the protective film 50.

The fourth semiconductor region 24 includes a portion located between the second electrode 12 (or the control wiring 13) and the terminal electrode 14 in the X direction. The fourth semiconductor region 24 reduces the concentration of the electric field in the semiconductor substrate 20, which might be caused by ions attracted to the second electrode 12 (or the control wiring 13) which has a lower voltage than that of the terminal electrode 14. For example, the fourth semiconductor region 24 promotes the extension of a depletion layer in the terminal region TR, thereby preventing the concentration of the electric field (refer to FIG. 14) caused by positive ions attracted to the second electrode 12 (or the control wiring 13). Since the concentration of the electric field is prevented, deterioration in the breakdown voltage of the semiconductor device can be further prevented.

The surface region 21t includes a portion of the insulating film 40 that is located between the second electrode 12 (or the control wiring 13) and the terminal electrode 14 in the X direction. The surface region 21t reduces the concentration of the electric field in the semiconductor substrate 20, which might be caused by ions attracted to the terminal electrode 14 which has a higher voltage than that of the second electrode 12 (or the control wiring 13). For example, it is possible to prevent chip destruction (refer to FIG. 15) that may occur when the electric field is concentrated due to negative ions attracted to the terminal electrode 14.

According to the semiconductor device 100 of the present embodiment, the insulating film 40 has unevenness provided on the upper surface thereof between the element region CR and the terminal electrode 14, and processing of the semiconductor substrate 20 is not required when the first upper surface 40a and the second upper surface 40b are formed. The first upper surface 40a and the second upper surface 40b are provided, for example, by etching the insulating film 40. Therefore, compared to a case in which the semiconductor substrate 20 must itself be etched to form unevenness, the influence on an impurity concentration distribution of the fourth semiconductor region 24 and the surface region 21t illustrated in FIG. 2B can be reduced. For example, the impurity concentration distribution of the fourth semiconductor region 24 and the surface region 21t each formed as a diffusion layer can be made more uniform, thereby making it possible to prevent the concentration of the electric field which might be caused by any non-uniformity in the impurity concentration distribution.

For example, as a comparative example, the following consideration is given as to a case in which the fourth semiconductor region 24 and the surface region 21t in FIG. 2B are formed as diffusion layers, and then the semiconductor substrate 20 is etched. The shapes of the diffusion layers change from an initial shape and impurity concentration profile due to the etching of the semiconductor substrate 20.

As another comparative example, the following consideration is given as to a case in which the fourth semiconductor region 24 and the surface region 21t in FIG. 2B are formed as diffusion layers after the semiconductor substrate 20 has been. Injecting impurities (dopants) from the upper surface of an etched, non-flat semiconductor substrate 20 may affect the profile of the diffusion layers.

### First Modification of First Embodiment

FIG. 3A is an enlarged cross-sectional view illustrating a first modification of the first embodiment. The portion (the region PR1 in FIG. 2A) in which the first upper surface 40a and the second upper surface 40b are formed between the insulating film 40 and the protective film 50 is shown enlarged.

The second upper surface 40b is the bottom surface of the recess portion CP. The recess portion CP is recessed in the negative Z direction from the upper surface of the insulating film 40 and has the second upper surface 40b, which is the bottom surface, and a side surface 40w between the first upper surface 40a and the second upper surface 40b of the insulating film 40.

The recess portion CP has a portion that increases in width (X direction dimension) toward the bottom surface. In the example of FIG. 3A, the recess portion CP has a portion with a width that is larger at a position below the first upper surface 40a than at the first upper surface 40a.

The recess portion CP illustrated in FIG. 3A is formed, for example, by wet etching. The formation method is not limited to wet etching, and another isotropic etching may be used. For example, the recess portion CP can be formed by an isotropic CDE process.

The structure of the recess portion CP according to this modification can further improve adhesion between the insulating film 40 and the protective film 50 by the anchor effect.

### Second Modification of First Embodiment

FIG. 3B is an enlarged cross-sectional view illustrating a second modification of the first embodiment. The portion (the region PR1 in FIG. 2A) in which the first upper surface 40a and the second upper surface 40b are formed between the insulating film 40 and the protective film 50 is shown enlarged. A description of aspects common to FIG. 3A will be omitted.

The structure of the recess portion CP according to the present modification can also further improve the adhesion between the insulating film 40 and the protective film 50 by the anchor effect.

An example of a manufacturing method of the recess portion CP having the shape illustrated in FIG. 3B will be described. For example, the method includes a step of forming the recess portion CP by removing portions of the insulating film 40 in etching process such as RIE, a step of forming a sidewall insulating layer on a sidewall of the recess portion CP, and a step of selectively removing the insulating film 40 located at the bottom of the recess portion CP. The insulating film 40 and the sidewall insulating layer can be different types of insulators. The insulating film 40 comprises, for example, silicon oxide. The sidewall insulating layer comprises, for example, polysilicon or silicon nitride. The insulating film 40 and the sidewall insulating layer thus have different etching rates in a wet etching process or the like. A wet etching solution may comprise, for example, buffered hydrogen fluoride (BHF). For example, the insulating film 40 has a higher etching rate with respect to BHF than that of the sidewall insulating layer.

### Second Embodiment

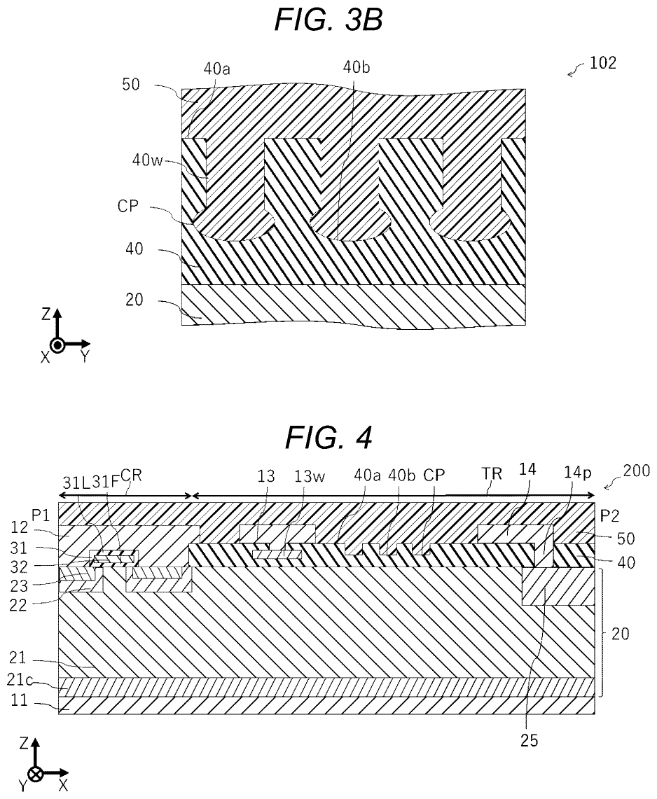

FIG. 4 is a cross-sectional view of a semiconductor device 200 according to a second embodiment. A description of aspects common to the semiconductor device 100 will be omitted.

In the second embodiment, the gate electrode 32 in the element region CR is a so-called planar gate. That is, the gate electrode 32 is provided on the semiconductor substrate 20 via the gate insulating portion 31. The gate insulating portion 31 includes the gate insulating film 31F formed to be thin between the semiconductor substrate 20 and the gate electrode 32, and the gate insulation layer 31L formed to be thick between the second electrode 12 and the gate electrode 32. The gate insulation layer 31L insulates the gate electrode 32 from the second electrode 12.

The gate electrode 32 faces a part of the second semiconductor region 22 (of the second conductivity type) with the gate insulating film 31F interposed therebetween. When a voltage equal to or higher than a threshold voltage is applied to the gate electrode 32, an inversion layer is formed in the portion of the second semiconductor region 22 which faces the gate insulating film 31F, and the semiconductor device 200 is turned on.

The gate electrode 32 extends in the Y direction. The gate electrode 32 is connected to the wiring 13w at position not specifically depicted in FIG. 4.

The semiconductor device 200 can prevent movement of moisture and ions contained in moisture in the terminal region TR even in a planar gate semiconductor device, thereby preventing deterioration in the breakdown voltage of the semiconductor device. The movement of moisture and ions contained in moisture is prevented by increasing a migration path distance from the terminal electrode 14 to the second electrode 12 (or the control wiring 13) along the interface between the insulating film 40 and the protective film 50. In addition, this manner of increasing migration path distance can improve adhesion between the insulating film 40 and the protective film 50 and prevent peeling therebetween, thereby making it possible to further prevent the movement of moisture and ions contained in moisture.

### Third Embodiment

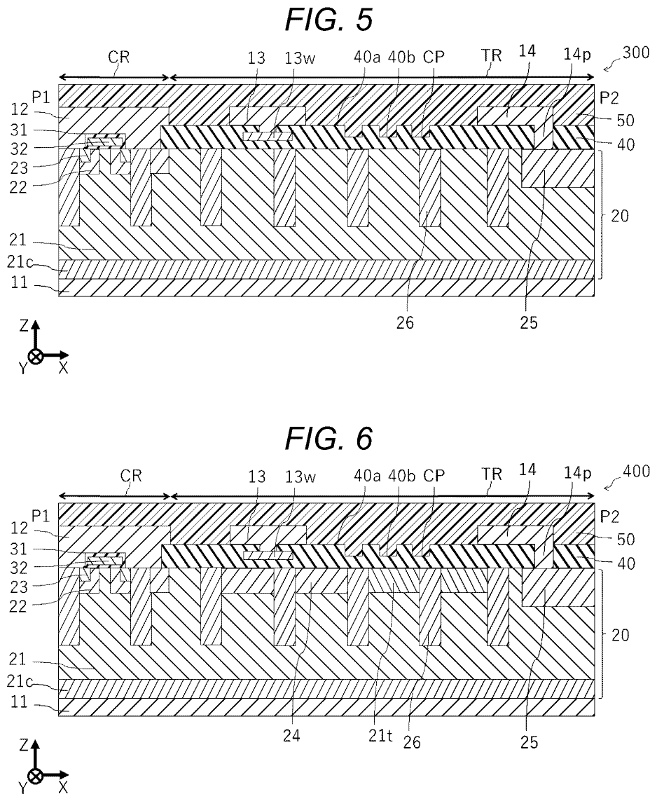

FIG. 5 is a cross-sectional view of a semiconductor device 300 according to a third embodiment. A description of aspects common to the semiconductor device 200 will be omitted.

In the third embodiment, the element region CR and the terminal region TR have a deep semiconductor region 26 (of the second conductivity type), which extends from the upper surface of the semiconductor substrate 20 into the first semiconductor region 21. In the element region CR, the deep semiconductor region 26 is provided between the gate electrodes 32 in an XY plane and extends in the Y direction. In the element region CR, the deep semiconductor region 26 is in contact with the second semiconductor region 22. In the element region CR, the deep semiconductor region 26 is in contact with the third semiconductor region 23. In the element region CR, the deep semiconductor region 26 is electrically connected to the second electrode 12.

A distance between the deep semiconductor region 26 and the first electrode 11 is shorter than a distance between the second semiconductor region 22 and the first electrode 11.

The deep semiconductor regions 26 are also provided in the terminal region TR and can be arranged with an equal interval therebetween in the X direction together with the deep semiconductor regions 26 provided in the element region CR. However, the plurality of deep semiconductor regions 26 do not necessarily need to be arranged with an equal interval therebetween. An interval between the adjacent deep semiconductor regions 26 in the element region CR may be different from an interval between the adjacent deep semiconductor regions 26 in the terminal region TR.

According to the semiconductor device 300 of the third embodiment, a depletion layer extends from an interface between the deep semiconductor region 26 and the first semiconductor region 21, thereby further preventing deterioration in the breakdown voltage of the semiconductor device. Alternatively, on-resistance can be reduced by increasing the impurity concentration in the first semiconductor region 21 while still maintaining the breakdown voltage of the semiconductor device.

### Fourth Embodiment

FIG. 6 is a cross-sectional view of a semiconductor device 400 according to a fourth embodiment. A description of aspects common to the semiconductor device 300 will be omitted.

In the fourth embodiment, the fourth semiconductor region 24 and the surface region 21t of the first semiconductor region 21 are provided between the deep semiconductor regions 26. The fourth semiconductor region 24 is located between deep semiconductor regions 26 that are provided closer to the terminal electrode 14 rather than deep semiconductor regions 26 in contact with the second electrode 12. The fourth semiconductor region 24 contains impurities of the same conductivity type as the deep semiconductor region 26. The impurity concentration of the fourth semiconductor region 24 is lower than the impurity concentration of the deep semiconductor region 26. The fourth semiconductor region 24 and the deep semiconductor region 26 are, for example, a p-type conductivity.

The surface region 21t is located between deep semiconductor regions 26 that are provided closer to the terminal electrode 14 rather than deep semiconductor regions 26 connected to the second electrode 12. The surface region 21t has a higher impurity concentration than that of the first semiconductor region 21 located closer to the first electrode 11 than the surface region 21t. The surface region 21t is provided, for example, closer to the terminal electrode 14 than to the fourth semiconductor region 24. The surface region 21t includes a portion that is located between the second electrode 12 and the terminal electrode 14 in the X direction.

Regarding a structural relationship in which the fourth semiconductor region 24 is located between adjacent deep semiconductor regions 26, although FIG. 6 illustrates two fourth semiconductor regions 24 separated by the deep semiconductor region 26, three or more fourth semiconductor regions 24 may be provided. Regarding a structural relationship in which the surface regions 21t is located between adjacent deep semiconductor regions 26, although FIG. 6 illustrates two surface regions 21t separated by the deep semiconductor regions 26, three or more surface regions 21t may be provided. In other words, the number and layout of the deep semiconductor regions 26, the fourth semiconductor regions 24, and the surface regions 21t are not limited to the structure illustrated in FIG. 6. The number and layout of the deep semiconductor regions 26, the fourth semiconductor regions 24, and the surface regions 21t can be appropriately selected depending on the design of the semiconductor device.

According to the semiconductor device 400 of the fourth embodiment, through the fourth semiconductor region 24 and the surface region 21t provided between the deep semiconductor regions 26, it is possible to reduce the influence on the depletion layer in the semiconductor substrate 20 when ions are present between the insulating film 40 and the protective film 50 and so prevent deterioration in the breakdown voltage of the semiconductor device.

The fourth semiconductor region 24 includes a portion located between the second electrode 12 (or the control wiring 13) and the terminal electrode 14 in the X direction. This portion of the fourth semiconductor region 24 reduces the concentration of the electric field in the semiconductor substrate 20, which might be caused by ions attracted to the second electrode 12 (or the control wiring 13). For example, it is possible to prevent the concentration of the electric field (refer to FIG. 14 caused by positive ions being attracted to the second electrode 12 (or the control wiring 13). Since the concentration of the electric field is prevented, the present embodiment can further prevent deterioration in the breakdown voltage of the semiconductor device.

The surface region 21t includes a portion located between the second electrode 12 (or the control wiring 13) and the terminal electrode 14 in the X direction. This portion of the surface region 21t reduces the concentration of the electric field in the semiconductor substrate 20, which can be caused by ions being attracted to the terminal electrode 14. For example, it is possible to prevent chip destruction (refer to FIG. 15) that may occur when negative ions are attracted to the terminal electrode 14 such that the concentration of the electric field occurs.

### Fifth Embodiment

FIG. 7 is a cross-sectional view of a semiconductor device 500 according to a fifth embodiment. A description of aspects common to the semiconductor device 100 will be omitted.

In the above description, a layout in which control wiring 13 is located between the second electrode 12 and the terminal electrode 14 was described, but embodiments are not necessarily limited thereto. The semiconductor device 100 illustrated in FIG. 7 is an example in which the second electrode 12 is located closer to the terminal region TR than to the control wiring 13, unlike the layout illustrated in FIG. 1. That is, the control wiring 13 does not necessarily surround the second electrode 12. For example, the control wiring 13 does not necessarily need to have the outer peripheral portion 13s that surrounds the second electrode 12, and the control wiring 13 and the wiring 13w may be located between second electrodes 12 in an XY plane. For example, an embodiment may adopt a layout in which the second electrode 12 is divided into two or more electrodes in the XY plane, and the control wiring 13 is located between these divided second electrodes 12.

In the semiconductor device 500 according to the fifth embodiment, charges such as ions may move between the insulating film 40 and the protective film 50 due to a voltage difference between the second electrode 12 and the terminal electrode 14. In other words, in the first to fourth embodiments described above, positive ions are not limited to being attracted to only the control wiring 13. In some cases, positive ions may be attracted to the second electrode 12.

### Sixth Embodiment

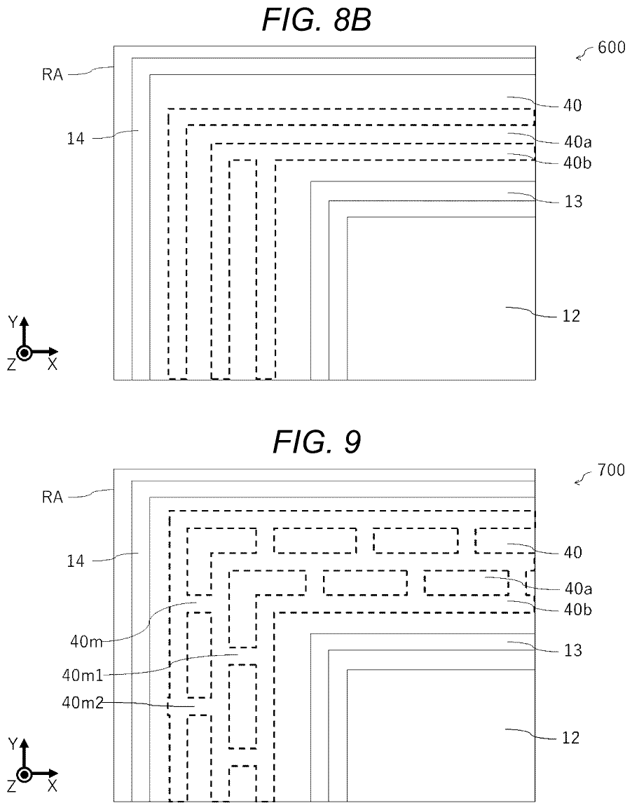

FIGS. 8A and 8B are enlarged schematic plan views of a portion of a semiconductor device according to a sixth embodiment, which corresponds to a region RA illustrated in FIG. 1. FIGS. 8A to 10 depict variations of the shape of a second plane 20b on the XY plane on an embodiment, and these variations may be appropriately combined with the first to fifth embodiments. Illustration of the protective film 50 is omitted for clarity in these figures.

A description will be given with reference to FIG. 8A. The upper surface of the insulating film 40 located between the control wiring 13 and the terminal electrode 14 includes the first upper surface 40a and the second upper surface 40b (the second upper surface 40b is a portion surrounded by dotted lines). In a portion located in the negative X direction with respect to the second electrode 12, the second upper surface 40b (the recess portion CP) extends in the Y direction. In a portion located in the positive Y direction with respect to the second electrode 12, the second upper surface 40b (the recess portion CP) extends in the X direction.

A portion of the second upper surface 40b (the recess portion CP), which extends in the X direction, and a portion of the second upper surface 40b (the recess portion CP), which extends in the Y direction, are continuous. The portion of the second upper surface 40b (the recess portion CP), which extends in the X direction and the portion of the second upper surface 40b (the recess portion CP), which extends in the Y direction intersect each other at the corner of a semiconductor device 600. As illustrated in FIG. 8A, the second upper surface 40b (the recess portion CP) arranged side by side in three rows intersect each other at three intersections located at the corners of the semiconductor device 600. It is noted that one or more rows of the second upper surface 40b (the recess portion CP) may be arranged, and the portion extending in the X direction and the portion extending in the Y direction may be continuous. The number of rows of the portions extending in the X direction of the second upper surface 40b (the recess portion CP) and the number of rows of the portions extending in the Y direction of the second upper surface 40b (the recess portion CP) are, for example, equal, but are not necessarily required to be equal and can be appropriately selected/varied according to the structure of the semiconductor device. For example, as illustrated in FIG. 8B, for each row of the portions extending in the X direction, two or more rows of the portions extending in the Y direction may be continuous, and an intersection between the portion extending in the X direction and the portion extending in the Y direction is not limited to a L-shape. The intersection may be formed to have a T-shape.

The semiconductor device 600 can further improve adhesion between the insulating film 40 and the protective film 50, thereby preventing peeling therebetween. The portion of the second upper surface 40b (the recess portion CP) that extends in the X direction and the portion of the second upper surface 40b (the recess portion CP) that extends in the Y direction are continuous with each other, thereby making it possible to further prevent peeling between the insulating film 40 and the protective film 50 in both the X direction and the Y direction.

For example, in the portion of the second upper surface 40b (the recess portion CP) that extends in the X direction, adhesion force in the X direction (adhesion force when a gap created by the peeling between the insulating film 40 and the protective film 50 progresses along the X direction) and adhesion force in the Y direction (adhesion force when the gap created by the peeling between the insulating film 40 and the protective film 50 progresses along the Y direction) may be different from each other. For example, the adhesion force in the X direction and the adhesion force in the Y direction are also different depending on the number of rows of the second upper surface 40b (the recess portion CP). In other words, the adhesion force in the X direction may be different from the adhesion force in the Y direction, and peeling may preferentially occur in a direction in which adhesion force is smaller.

Similarly, in the portion of the second upper surface 40b (the recess portion CP) that extends in the Y direction, adhesion force in the X direction may be different from adhesion force in the Y direction, and peeling may preferentially occur in the direction in which adhesion force is smaller.

In the sixth embodiment, the portion of the second upper surface 40b (the recess portion CP) that extends in the X direction and the portion of the second upper surface 40b (the recess portion CP) that extends in the Y direction are continuous, thereby making it possible to reduce differences in adhesion force in the X direction and the Y direction, and to prevent peeling in both the X direction and the Y direction. For example, when the terminal regions TR are provided with an equal length in the X direction and the Y direction, the number of portions of the second upper surface 40b (recess portion CP) extending in the X direction and the Y direction may be equal to one another.

The following description is based on the assumption that adhesion force is relatively small in a direction in which the second upper surface 40b (the recess portion CP) extends. For example, the portion of the second upper surface 40b (the recess portion CP) extending in the X direction may peel off in the X direction when the adhesion force is relatively small. On the other hand, in the portion extending in the Y direction, which is continuous with the portion of the second upper surface 40b (the recess portion CP) extending in the X direction, adhesion force in the X direction is relatively large. Therefore, peeling in the X direction can be prevented. Conversely, in the portion extending in the Y direction, the adhesion force in the Y direction is relatively small, but in the portion extending in the X direction, which is continuous with the portion extending in the Y direction, the adhesion force in the Y direction is relatively large. Therefore, peeling in the Y direction can be prevented.

### Seventh Embodiment

FIG. 9 is a cross-sectional view of a semiconductor device 700 according to a seventh embodiment. A description of aspects common to the semiconductor device 600 will be omitted.

FIG. 9 is an enlarged schematic plan view of a portion of the semiconductor device according to the seventh embodiment, which corresponds to the region RA illustrated in FIG. 1. Illustration of the protective film 50 is omitted.

In the seventh embodiment, a connection region 40m that extends in the Y direction and connects the plurality of second upper surfaces 40b to each other is provided between the second upper surfaces 40b formed to extend in the X direction and arranged in a plurality of rows in the Y direction. The connection region 40m that extends in the X direction and connects the plurality of second upper surfaces 40b to each other is provided between the second upper surfaces 40b formed to extend in the Y direction and arranged in a plurality of rows in the X direction. The connection region 40m is, for example, a flat surface that is smoothly continuous with the second upper surface 40b.

The connection region 40m is provided at a position closer to the second upper surface 40b than to the first upper surface 40a in the Z direction. For example, the connection region 40m is provided at the same position as the second upper surface 40b in the Z direction. The connection region 40m has, for example, the same width as that of the second upper surface 40b. In other words, the dimension (width) in the Y direction of the second upper surface 40b extending in the X direction is equal to the dimension (width) in the Y direction of the connection region 40m extending in the X direction. Alternatively, the dimension (width) in the X direction of the second upper surface 40b extending in the Y direction is equal to the dimension (width) in the X direction of the connection region 40m extending in the Y direction. For example, the connection region 40m may be formed in the same process as the process of removing the insulating film 40 for formation of the second upper surface 40b.

Hereinafter, as an example, referring to FIG. 9, a description will be given as to a case in which three or more rows of the second upper surfaces 40b are formed. The second upper surface 40b has an innermost second upper surface 40b (closest to the control wiring 13), an outermost second upper surface 40b (closest to the terminal electrode 14), and one or more intermediate second upper surfaces 40b located between the innermost second upper surface 40b and the outermost second upper surface 40b.

The connection region 40m has a first portion 40m1 connecting the innermost second upper surface 40b to the intermediate second upper surface 40b, and a second portion 40m2 connecting the outermost second upper surface 40b to the intermediate second upper surface 40b. For example, the second portion 40m2 is located between the adjacent first portions 40m1 in the Y direction, and the first portion 40m1 is located between the adjacent second portions 40m2 in the Y direction.

When two rows of the second upper surfaces 40b are formed, the second upper surfaces 40b have the innermost second upper surface 40b (closest to the control wiring 13) and the outermost second upper surface 40b (closest to the terminal electrode 14). The connection region 40m connects the innermost second upper surface 40b to the outermost second upper surface 40b. Therefore, it is not necessary for one or more intermediate second upper surfaces 40b to be provided.

According to the semiconductor device 700 of the seventh embodiment, adhesion between the insulating film 40 and the protective film 50 can be further improved, and peeling therebetween can be prevented. The portion of the second upper surface 40b (the recess portion CP) extending in the X direction and the portion of the second upper surface 40b (the recess portion CP) extending in the Y direction are continuous, thereby making it possible to limit peeling in both the X direction and the Y direction.

In the seventh embodiment, the connection region 40m is provided. For example, the connection region 40m extending in the Y direction is provided between the portions of the adjacent second upper surfaces 40b, which extend in the X direction. Even if adhesion force is relatively weak (or strong) in a direction in which the second upper surface 40b extends, the effect of preventing peeling in both the X direction and the Y direction can be further improved by mixing the portions of the second upper surface 40b, which respectively extend in the X direction and the Y direction.

Furthermore, according to the seventh embodiment, in the second upper surfaces 40b formed in a plurality of rows, the innermost second upper surface 40b and an intermediate second upper surface 40b are connected to each other by the connection region 40m (the first portion 40m1 in FIG. 9). Further, the outermost second upper surface 40b and the intermediate second upper surface 40b are connected to each other by the connection region 40m (the second portion 40m2 in FIG. 9). Therefore, when the protective film 50 is embedded, the material of the protective film 50 can move between the second upper surfaces 40b extending in parallel. The second upper surfaces 40b in a plurality of rows can thus be reliably embedded with a protective film 50 having little material bias. Adhesion between the insulating film 40 and the protective film 50 can be further improved.

Furthermore, according to the seventh embodiment, movement of moisture and ions contained in moisture at an interface between the insulating film 40 and the protective film 50 can be further prevented, and thus deterioration in the breakdown voltage of the semiconductor device can be further prevented. Compared to the structure shown in FIG. 8A, in the seventh embodiment, the connection region 40m extending in the Y direction is located between the portions of the second upper surface 40b, which extend in the X direction. Therefore, the migration path distance for moisture and ions that attempt to move in the X direction along the first upper surface 40a located between the portions of the second upper surface 40b that extend in the X direction is lengthened by the connection region 40m. The connection region 40m can thus serve to prevent the movement of moisture and ions in the direction in which the second upper surface 40b extends. By preventing local concentration of moisture and ions and preventing electric field concentration in the semiconductor substrate 20, it is possible to further prevent deterioration in the breakdown voltage of the semiconductor device.

### Eighth Embodiment

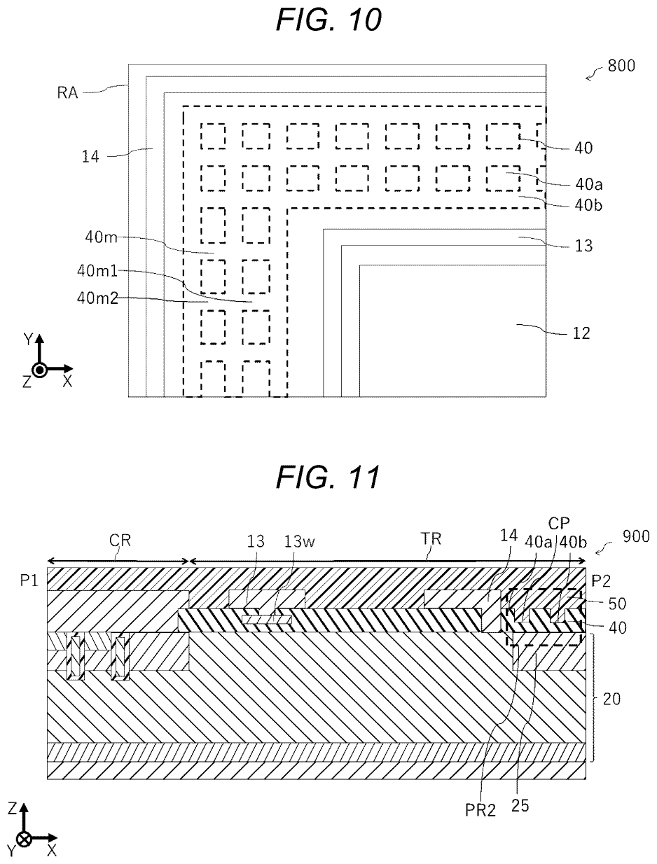

FIG. 10 is a cross-sectional view of a semiconductor device 800 according to an eighth embodiment. A description of aspects common to the semiconductor device 600 will be omitted.

FIG. 10 is an enlarged schematic plan view of a portion of the semiconductor device according to the eighth embodiment, which corresponds to the region RA illustrated in FIG. 1. Illustration of the protective film 50 is omitted.

In the eighth embodiment, the connection region 40m connects the innermost second upper surface 40b, one or more intermediate second upper surfaces 40b, and the outermost second upper surface 40b to each other. The connection region 40m has the first portion 40m1 connecting the innermost second upper surface 40b to an intermediate second upper surface 40b, and the second portion 40m2 connecting the outermost second upper surface 40b to an intermediate second upper surface 40b. The first portion 40m1 and the second portion 40m2 are located on the same straight line in the X direction or the Y direction. The first portion 40m1 and the second portion 40m2 extending in the X direction overlap at least partially with straight lines in the X direction. The second upper surface 40b is provided in a lattice pattern.

According to the semiconductor device 800 of the eighth embodiment, adhesion between the insulating film 40 and the protective film 50 can be further improved, and thus peeling therebetween can be prevented. The portion of the second upper surface 40b (the recess portion CP) extending in the X direction and the portion of the second upper surface 40b (the recess portion CP) extending in the Y direction are continuous, thereby further limiting peeling in both the X direction and the Y direction.

### Ninth Embodiment

FIG. 11 is a cross-sectional view of a semiconductor device 900 according to a ninth embodiment. A description of aspects common to the semiconductor device 100 will be omitted.

The semiconductor device 900 according to the ninth embodiment has the first upper surface 40a and the second upper surface 40b on the upper surface of the insulating film 40, which is farther away from the element region CR than the terminal electrode 14 in the terminal region TR.

It is noted that, in the ninth embodiment, the first upper surface 40a and the second upper surface 40b may be provided on the upper surface of the insulating film 40 between the element region CR and the terminal electrode 14. The shape of the recess portion CP shown as the first or second modification of the first embodiment may be provided.

The semiconductor device 900 according to the ninth embodiment can prevent infiltration of moisture from the outside of the semiconductor device at the side surface of a device package, thereby making it possible not only to prevent the concentration of the electric field in the semiconductor substrate 20, but also to prevent deterioration in the breakdown voltage of the semiconductor device due to infiltration of moisture and the like.

Since the first upper surface 40a and the second upper surface 40b are provided on the upper surface of the insulating film 40, which is farther away from the element region CR than the terminal electrode 14 in the terminal region TR, a migration path distance between the insulating film 40 and the protective film 50 is increased such that the time until moisture and ions from the side surface of a package reach the terminal electrode 14 is increased. The moisture from the side surface of the package (and the ions contained in the moisture) are prevented from moving beyond the terminal electrode 14 toward the element region CR. Since the moisture and the ions are prevented from reaching the terminal electrode 14 and moving beyond the terminal electrode 14, movement of the moisture and the ions due to a voltage difference between the second electrode 12 or the control wiring 13 and the terminal electrode 14 is reduced. Therefore, the movement of the moisture and ions and the local concentration thereof can be prevented, and the electric field concentration in the semiconductor substrate 20 can be reduced.

### Modification of Seventh Embodiment

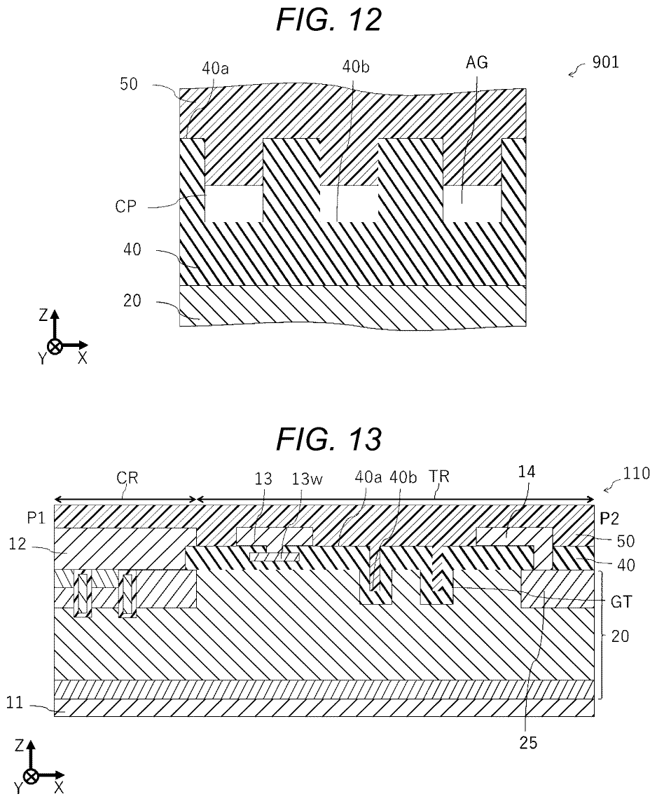

FIG. 12 is an enlarged cross-sectional view illustrating a semiconductor device 901 according to a modification of the seventh embodiment. A portion in which the first upper surface 40a and the second upper surface 40b are formed between the insulating film 40 and the protective film 50 (a region PR2 indicated by dashed lines in FIG. 11) is shown enlarged.

In the present modification, a gap AG (an air layer) is present between the second upper surface 40b, which is the bottom surface of the recess portion CP, and the protective film 50. The air layer AG is not limited to comprising a gas having the same composition as ambient air, but may contain any substance in a gaseous state.

In the present modification, since moisture is trapped in the air layer AG between the second upper surface 40b and the protective film 50, movement of moisture and ions at the upper surface of the insulating film 40 can be further prevented. The electric field concentration in the semiconductor substrate 20, which can be caused by the local concentration of moisture and ions contained in moisture around the second electrode 12, the control wiring 13, and the terminal electrode 14, can be prevented, and thus deterioration in the breakdown voltage of the semiconductor device can be prevented.

Since migration path distance is increased by the uneven structure formed by the first upper surface 40a and the second upper surface 40b, infiltration of moisture and ions contained in moisture is reduced, and moisture and ions therein are trapped in the air layer AG, thereby further preventing infiltration of moisture and ions.

In addition, since moisture and ions trapped by the air layer are located farther away from the element region CR than the terminal electrode 14, the influence of the trapped moisture and ions on the extension of a depletion layer can be reduced. In other words, in the present modification, by trapping moisture and ions in a region that is farther away from the element region CR than the terminal electrode 14 and in which the influence on the breakdown voltage of the semiconductor device is relatively small, electrical characteristics of a region closer to the element region CR than to the terminal electrode 14 and in which the influence on the breakdown voltage of the semiconductor device is relatively large can be further stabilized.

In the semiconductor devices 900 and 901, infiltration of moisture and ions contained in moisture from the side surface of a semiconductor package can be prevented by the unevenness formed in the upper surface of the insulating film 40, which is farther away from the element region CR than the terminal electrode 14, thereby preventing deterioration in the breakdown voltage of the semiconductor device and improving reliability.

### Tenth Embodiment

FIG. 13 is a cross-sectional view of the semiconductor device 110 according to a tenth embodiment. A description of aspects common to the semiconductor device 100 will be omitted.

In the tenth embodiment, a groove GT is formed in the upper surface of the semiconductor substrate 20 in the terminal region TR, and the insulating film 40 is formed on the bottom surface and side walls of the groove GT. In the tenth embodiment, the groove GT is formed in the upper surface of the semiconductor substrate 20 in the terminal region TR. The insulating film 40 is formed in the groove GT.

A distance in the Z direction between the second upper surface 40b of the insulating film 40 and the first electrode 11 is shorter than a distance in the Z direction between the first upper surface 40a and the first electrode 11.

The semiconductor device 110 according to the tenth embodiment also limits movement of moisture and ions therein by increasing the migration path distance along the insulating film 40 between the second electrode 12 (or the control wiring 13) and the terminal electrode 14, and thus deterioration in the breakdown voltage of the semiconductor device can be prevented. A lower voltage than that of the terminal electrode 14 may be applied to the second electrode 12 (or the control wiring 13), and moisture and ions therein may move due to a voltage difference. In the tenth embodiment, since the first upper surface 40a and the second upper surface 40b are provided, the movement of moisture and ions therein can be prevented, and the influence on a depletion layer of the semiconductor substrate 20 can be reduced.

According to at least one of the embodiments described above, since the first upper surface 40a and the second upper surface 40b are provided on the upper surface of the insulating film 40, the concentration of the electric field in the semiconductor substrate 20 can be prevented, and deterioration in the breakdown voltage of the semiconductor device can be prevented. According to at least one of the embodiments described above, deterioration in the breakdown voltage, which is caused by generation of moisture or ions contained in moisture inside the semiconductor device, can be prevented, and moisture resistance of the semiconductor device can be improved.

The embodiments have been described above with reference to specific examples. However, the embodiments are not limited to these specific examples. In other words, designs obtained by appropriately modifying these specific examples by a person skilled in the art are also included within the scope of the embodiments as long as the designs have the characteristics of the embodiments. Each element provided in each of the specific examples described above, and the arrangement, material, condition, shape, size, and the like thereof are not limited to those described in the examples, and can be modified as appropriate.

Furthermore, the respective elements described for different embodiments can be combined with each other to the extent technically feasible, and the combinations thereof is also included within the scope of the present disclosure. In addition thereto, within the scope of the present disclosure, various modifications and alterations will be apparent to a person skilled in the art, and it is to be understood that these modifications and alterations also fall within the scope of the present disclosure.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor substrate having an element region and a terminal region surrounding the element region;
a first electrode on a first side of the semiconductor substrate;
a second electrode on a second side of the semiconductor substrate in the element region;
an insulating film on the semiconductor substrate;
a control wiring on the insulating film;
a terminal electrode with a portion on the semiconductor substrate with the insulating film interposed therebetween in the terminal region; and
a protective film on the insulating film, wherein
the insulating film has an upper surface contacting the protective film in the terminal region,
the upper surface has a first upper surface portion and a second upper surface portion, and
a distance between the first electrode and the second upper surface portion is less than a distance between the first electrode and the first upper surface portion.

2. The semiconductor device according to claim 1, wherein the insulating film includes a plurality of recess portions.

3. The semiconductor device according to claim 2, wherein the second upper surface portion is a bottom surface of a recess portion.

4. The semiconductor device according to claim 3, wherein a width of the recess portion is greater than a width of an opening of the recess portion adjacent to the first upper surface portion.

5. The semiconductor device according to claim 2, wherein the plurality of recess portions are continuous and surround the element region.

6. The semiconductor device according to claim 2, wherein the plurality of recess portions surround the element region but are not continuous.

7. The semiconductor device according to claim 1, wherein the second upper surface portion of the insulating film is at a position between the control wiring and the terminal electrode.

8. The semiconductor device according to claim 1, wherein the terminal electrode is a position between the second upper surface portion of the insulating film and the control wiring.

9. The semiconductor device according to claim 8, wherein a gap is between the second upper surface portion and the protective film.

10. The semiconductor device according claim 1, wherein the semiconductor substrate includes:
a first semiconductor region of a first conductivity type;
a second semiconductor region of a second conductivity type, the second semiconductor region being on the first semiconductor region in the element region;
a third semiconductor region of the first conductivity type, the third semiconductor region being on the second semiconductor region in the element region and electrically connected to the second electrode; and
a fourth semiconductor region of the second conductivity type, the fourth semiconductor region being on the first semiconductor region and located closer to the terminal electrode than to the second semiconductor region in a second direction from the element region to the terminal region.

11. The semiconductor device according to claim 10, wherein
the first semiconductor region has a surface region in contact with the insulating film in the terminal region,
the impurity concentration of the first conductivity type in the surface region is higher than the impurity concentration of the first conductivity type in a portion of the first semiconductor region outside and below the surface region, and
the surface region includes a portion between the fourth semiconductor region and the terminal electrode in the second direction.

12. A semiconductor device, comprising:
a semiconductor substrate having an element region and a terminal region surrounding the element region;
a first electrode on a first side of the semiconductor substrate;
a second electrode on a second side of the semiconductor substrate in the element region;
an insulating film on the second side of the semiconductor substrate in the terminal region, the insulating film having a first portion with a first thickness and a second portion with a second thickness less than the first thickness;
a control wiring on the insulating film in the terminal region;
a terminal electrode with a portion on the semiconductor substrate with the insulating film interposed therebetween in the terminal region; and
a protective film on the insulating film, the protective film directly contacting a first upper surface of the first portion of the insulating film.

13. The semiconductor device according to claim 12, wherein the protect film directly contacts a second upper surface of the second portion of the insulating film.

14. The semiconductor device according to claim 12, wherein the second portion of the insulating film is a bottom of a recess portion formed in the insulating film.

15. The semiconductor device according to claim 14, wherein a width of the recess portion is greater than a width of an opening of the recess portion adjacent to the first upper surface.

16. The semiconductor device according to claim 12, wherein the second portion of the insulating film surrounds the element region.

17. The semiconductor device according to claim 12, wherein the second portion of the insulating film is at a position between the control wiring and the terminal electrode.

18. The semiconductor device according claim 12, wherein the semiconductor substrate includes:
a first semiconductor region of a first conductivity type;
a second semiconductor region of a second conductivity type, the second semiconductor region being on the first semiconductor region in the element region;
a third semiconductor region of the first conductivity type, the third semiconductor region being on the second semiconductor region in the element region and electrically connected to the second electrode; and
a fourth semiconductor region of the second conductivity type, the fourth semiconductor region being on the first semiconductor region and located closer to the terminal electrode than to the second semiconductor region in a second direction from the element region to the terminal region, wherein
the first semiconductor region has a surface region in contact with the insulating film in the terminal region,
the impurity concentration of the first conductivity type in the surface region is higher than the impurity concentration of the first conductivity type in a portion of the first semiconductor region outside and below the surface region, and
the surface region includes a portion between the fourth semiconductor region and the terminal electrode in the second direction.

19. A manufacturing method for a semiconductor device, the manufacturing method comprising:
preparing a semiconductor substrate having an element region having an upper surface electrode and a terminal region surrounding the element region;
forming an insulating film on the semiconductor substrate;
forming a terminal electrode on the insulating film in the terminal region;
forming a recess portion in the insulating film between the upper surface electrode and the terminal electrode, the recess portion being formed by partially removing the insulating film but the depth of the recess portion being less than a total thickness of the insulating film; and
forming a protective film on the recess portion of the insulating film.

20. The manufacturing method according to claim 19, wherein the forming of the recess portion includes forming, an insulating layer of a different type than the insulating film on a sidewall of the recess portion.
